(19) United States
(12) Patent Application Publication
(10) Pub. No.: US 2024/0213197 A1
(43) Pub. Date: Jun. 27, 2024

(54) NITRIDE-BASED SEMICONDUCTOR DEVICE AND METHOD FOR MANUFACTURING THE SAME

(71) Applicant: INNOSCIENCE (ZHUHAI) TECHNOLOGY CO., LTD., ZHUHAI CITY (CN)

(72) Inventors: Haohua MA, ZHUHAI CITY (CN); Sichao LI, ZHUHAI CITY (CN)

(21) Appl. No.: 17/918,322

(22) PCT Filed: Jul. 20, 2022
(86) PCT No.: PCT/CN2022/106822

§ 371 Date: Oct. 11, 2022

(51) Int. Cl. H01L 23/00

(52) U.S. Cl. CPC H01L 24/13; H01L 24/05; H01L 24/11; H01L 24/27; H01L 24/29; H01L 24/73; H01L 2224/0401; H01L 2224/1012; H01L 2224/1184; H01L 2224/13016; H01L 2224/2784; H01L 2224/29016; H01L 2224/73104

(57) ABSTRACT

A nitride-based semiconductor device includes a nitride-based semiconductor wafer, a protecting layer, and a plurality of connecting bumps. The nitride-based semiconductor wafer comprises a plurality of nitride-based dies. Each of the nitride-based dies comprises a connecting surface and a plurality of connecting pads and the connecting pads are embedded in the connecting surface. The protecting layer is disposed on the connecting surfaces of the nitride-based dies. The connecting bumps are embedded in the protecting layer. Every connecting bump connects one of the connecting pads. Every connecting bump has a first polished plane, and the first polished plane is free from the protecting layer. A manufacturing method of nitride-based semiconductor device is also provided.

### FIELD OF THE INVENTION

The present invention generally relates to a nitride-based semiconductor device. More specifically, the present invention relates to a nitride-based semiconductor device having connecting bumps that is embedded in a protecting layer.

### BACKGROUND

In recent years, intense research on high-electron-mobility transistors (HEMTs) has been prevalent, particularly for high power switching and high frequency applications. III-nitride-based HEMTs utilize a heterojunction interface between two materials with different bandgaps to form a quantum well-like structure, which accommodates a two-dimensional electron gas (2DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET). In recent days, nitride-based semiconductor device comprising HEMTs is electrically connected to other devices through solder bumps, and an underfill (or underfill epoxy) will be applied to absorb stress during falling tests, high temperature tests, and low temperature tests. However, during the applying or injection processes, bubbles and air gaps might be formed between the solder bumps or around the interfaces between the solder bump and the nitride-based semiconductor device. These bubbles and air gaps are adjacent to the solder bumps, and electromigration of tin might happen. Electromigration of the solder bumps may lower the withstanding voltage, causing short circuit, and the reliability of the nitride-based semiconductor device will be affected. Therefore, a nitride-based semiconductor device with proper electro-connecting interface is required.

### SUMMARY OF THE INVENTION

In accordance with one aspect of the present disclosure, a nitride-based semiconductor device is provided. The nitride-based semiconductor device includes a nitride-based semiconductor wafer, a protecting layer, and a plurality of connecting bumps. The nitride-based semiconductor wafer comprises a plurality of nitride-based dies. Each of the nitride-based dies comprises a connecting surface and a plurality of connecting pads, and the connecting pads are embedded in the connecting surface. The protecting layer is disposed on the connecting surfaces of the nitride-based dies. The connecting bumps are embedded in the protecting layer. Every connecting bump connects one of the connecting pads. Every connecting bump has a first polished plane, and the first polished plane is free from the protecting layer.

In accordance with one aspect of the present disclosure, method for manufacturing a nitride-based semiconductor device is provided. The method includes steps as follows. Disposing a plurality of connecting bumps on a nitride-based semiconductor wafer; disposing the nitride-based semiconductor wafer in a container; disposing a dielectric material on the nitride-based semiconductor wafer in the container; solidifying the dielectric material and form a protecting layer; and polishing the connecting bumps. The connecting bumps are facing upward. A first polished plane is formed on every connecting bump. The nitride-based semiconductor wafer comprises a plurality of nitride-based dies. The nitride-based die comprises a connecting surface and a plurality of connecting pads embedded in the connecting surface. Every connect bump connects one of the connecting pads, and the protecting layer is disposed on the connecting surfaces of the nitride-based dies.

In accordance with one aspect of the present disclosure, a nitride-based semiconductor device is provided. The nitride-based semiconductor device comprises a protecting layer, a plurality of connecting bumps, and a plurality of nitride-based dies. The connecting bumps are embedded in the protecting layer. The nitride-based dies are disposed on the protecting layer. The connecting bumps electrically connect the nitride-based dies. Every connecting bump has a first polished plane, and the first polished planes of the connecting bumps are free from coverage of the protecting layer and the nitride-based dies.

By applying the above configuration, the configuration is made for better. Since the connecting bumps are embedded in the protecting layer, and every connecting bump has a first polished plane for electrical connection, thereby improving the structure between the connecting bumps and the nitride-based dies, and the first polished planes may form a proper electrical connection with other devices.

### BRIEF DESCRIPTION OF THE DRAWINGS

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIG. 1 is a top view of a nitride-based semiconductor device according to some embodiments of the present disclosure;

FIG. 2 is a side sectional view according to a cutting plane line 2 in FIG. 1;

FIG. 3 is another side sectional view of the nitride-based semiconductor device according to the embodiments of the present disclosure;

FIG. 4 is a side sectional view according to a cutting plane line 4 in FIG. 1;

FIG. 5 is a side sectional view of a nitride-based semiconductor device according to some embodiments of the present disclosure;

FIG. 6 is a side sectional view of a nitride-based semiconductor device according to other embodiments of the present disclosure;

FIGS. 7-12 are side sectional views of steps of a manufacturing method of nitride-based semiconductor device of some embodiments of the present disclosure; and

FIGS. 13-15 are side sectional views of steps of a manufacturing method of nitride-based semiconductor device of some other embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “above,” “on,” “below,” “up,” “left, ” “right,” “down,” “top,” “bottom,” “vertical, ” “horizontal,” “side, ” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Further, it is noted that the actual shapes of the various structures depicted as approximately rectangular may, in actual device, be curved, have rounded edges, have somewhat uneven thicknesses, etc. due to device fabrication conditions. The straight lines and right angles are used solely for convenience of representation of layers and features.

In the following description, nitride-based semiconductor devices/dies/packages, methods for manufacturing the same, and the likes are set forth as preferred examples. It will be apparent to those skilled in the art that modifications, including additions and/or substitutions may be made without departing from the scope and spirit of the present disclosure. Specific details may be omitted so as not to obscure the present disclosure; however, the disclosure is written to enable one skilled in the art to practice the teachings herein without undue experimentation.

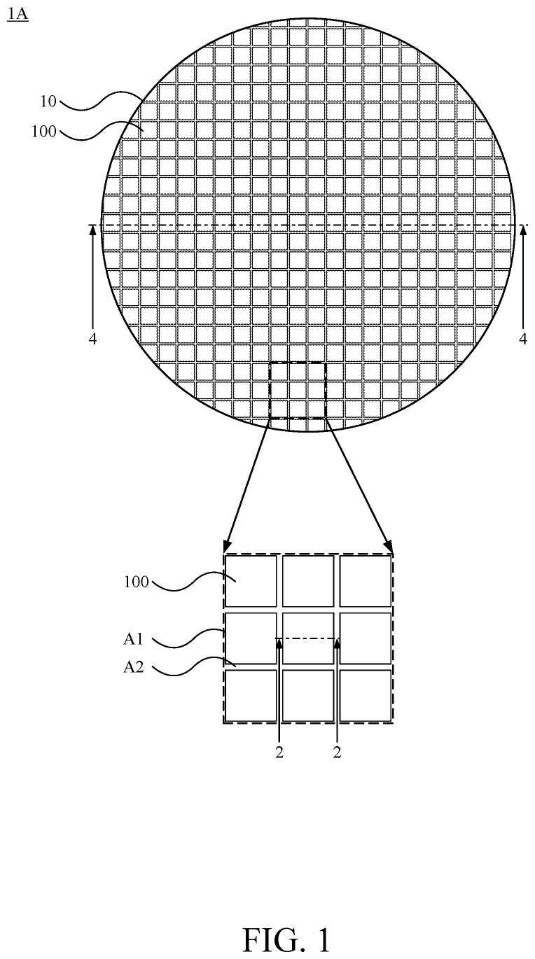

FIG. 1 is a top view of a nitride-based semiconductor device according to some embodiments of the present disclosure. Referring to FIG. 1, the nitride-based semiconductor device 1A comprises a nitride-based semiconductor wafer 10. In this embodiment, the nitride-based semiconductor wafer 10 contains nitride material. For example, the nitride-based semiconductor wafer 10 has gallium nitride (GaN) and aluminum gallium nitride (AlGaN), and a diameter of the nitride-based semiconductor wafer 10 is 200 mm, and a thickness of the nitride-based semiconductor wafer 10 is 1 mm. Therefore, the nitride-based semiconductor wafer 10 is thick enough to endure polishing during the manufacturing process, and the nitride-based semiconductor wafer 10 has enough area and thickness to be processed in a wafer-level chip scale packaging (WLCSP). In some embodiment, the diameter of the nitride-based semiconductor wafer 10 falls in a range from 150 mm to 300 mm, and the thickness of the nitride-based semiconductor wafer 10 falls in a range from 0.5 mm to 2 mm.

The nitride-based semiconductor wafer 10 comprises a plurality of nitride-based dies 100. In other words, the nitride-based semiconductor device 1A comprises the nitride-based dies 100, and the nitride-based dies 100 are horizontally connected and formed a wafer.

In this embodiment, the nitride-based dies 100 comprises a GaN layer and an AlGaN layer, and the AlGaN layer is disposed on the GaN layer. A bandgap of the AlGaN layer is higher than a bandgap of the GaN layer, and a 2DEG region is formed. The GaN layer and the AlGaN layer can form one or multiple HEMT devices in the nitride-based die 100.

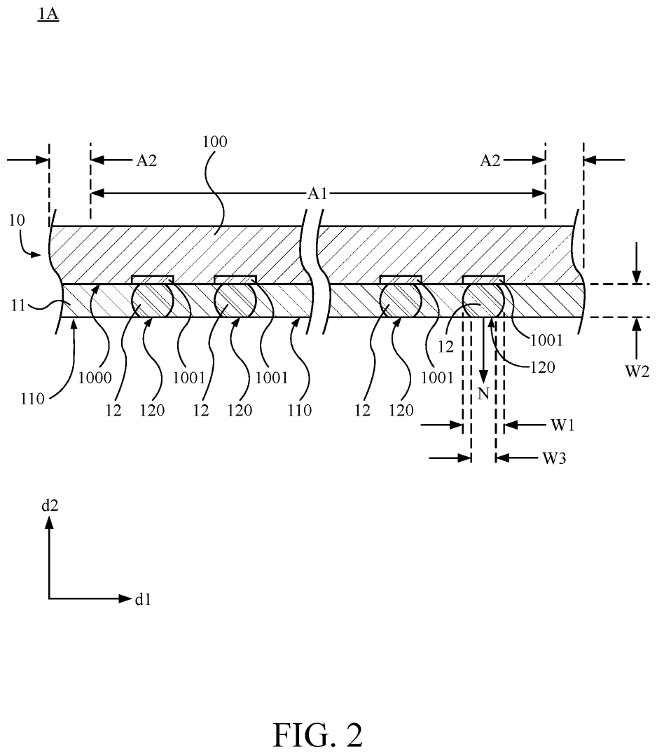

FIG. 2 is a side sectional view according to a cutting plane line 2 in FIG. 1. In order to clearly explain the device, FIG. 2 and the following side sectional views show a sectional view of only one or two nitride-based dies. However, the present disclosure is not limited to the number shown in these side sectional views, and a plurality of nitride-based dies of the nitride-based semiconductor wafer should be considered in the following description. Referring to FIG. 2, the nitride-based semiconductor device 1A comprises a protecting layer 11 and a plurality of connecting bumps 12. Moreover, each of the nitride-based dies 100 comprises a connecting surface 1000 and a plurality of connecting pads 1001, and the connecting pads 1001 are embedded in the connecting surface 1000.

The protecting layer 11 is disposed on the connecting surfaces 1000 of the nitride-based dies 100. To be specific, in the nitride-based semiconductor wafer 10, the connecting surfaces 1000 of the connected nitride-based dies 100 are arranged in the same level of plane. The connecting surfaces 1000 form a carrying plane, and the protecting layer 11 is disposed on the carrying plane form by connecting surfaces 1000.

In this embodiment, the connecting bumps 12 are embedded in the protecting layer 11, and the connecting bumps 12 are distributed on the connecting pads 1001. Most of the surface of the connecting bump 12 is surrounded by the protecting layer 11 or the connecting pad 1001 closely. In other words, only part of the connecting bump 12 is exposed by the protecting layer 11, and the rest of the connecting bump 12 is covered by the protecting layer 11 or the connecting pad 1001.

Every connecting bump 12 connects one of the connecting pads 1001, and the connecting bumps 12 electrically connects the nitride-based dies 100 through the connecting pads 1001. A plurality of interfaces are formed between the connecting bumps 12 and the connecting pads 1001, and the interfaces are spread along the same plane. In other words, the interfaces are substantially coplanar.

In this embodiment, every connecting bump 12 has a polished plane 120, and the polished plane 120 is free from the protecting layer 11. The polished planes 120 face backward towards the nitride-based dies 100, and the polished planes 120 of the connecting bumps 12 provide proper electric-connecting interfaces. In every connecting bump 12, the surface connected to the nitride-based die 100 is covered by the connecting pad 1001, and the polished plane 120 is exposed by the protecting layer 11, and the rest of the surface of the connecting bump 12 is covered by the protecting layer 11. In other words, a surface of the protecting layer 11 is connected to the connecting surface 1000, and another surface of the protecting layer 11, which is opposite to the surface connected to the connecting surface 1000, and the polished planes 120 are coplanar or nearly coplanar. No bubble or air gaps is formed around the connecting bumps 12.

Moreover, the polished planes 120 of the connecting bumps 12 are polished, and the polished planes 120 are coplanar. Therefore, the nitride-based dies 100 of the nitride-based semiconductor device 1A can be electrically connected through the polished planes 120. The protecting layer 11 fill up the spaces between the connecting bumps 12, and the protecting layer 11 can absorb the stress between the connecting bumps 12. Therefore, the nitride-based semiconductor device 1A can endure falling tests, high temperature tests, and low temperature tests. Also, no bubble or air gaps is formed around the connecting bumps 12, so the connecting bumps 12 surrounded closely by the protecting layer 11 can prevent electromigration, and the connecting bumps 12 can maintain a proper electrical connection. For example, the connecting bumps 12 may include tin, and the connecting bumps 12 embedded in the protecting layer 11 can avoid electromigration.

In this embodiment, the polished planes 120 are coplanar. Therefore, the nitride-based die 100 can be properly electrically connected to a printed circuit board. Also, since the polished planes 120 are located on the same level of plane, the protecting layer 11 can properly hold the connecting bumps 12. Furthermore, coplanar polished planes 120 can be formed easily through a polish process.

Referring to FIG. 1, the nitride-based semiconductor wafer 10 has a plurality of die areas A1 and a dicing area A2. The dicing area is located among the die areas A1, and each of the nitride-based dies 100 is disposed in one of the die areas A1. The protecting layer 11 covers a surface of the nitride-based semiconductor wafer 10 in the dicing area A2. In other words, the protecting layer 11 fills up the surface of the nitride-based semiconductor wafer 10 in the die areas A1 and the dicing area A2, and the protecting layer 11 can hold the connecting bumps 12 and form a plane surface, and the connecting bumps 12 can be polished easily to form the polished surfaces 120.

Referring to FIG. 2, no gap or bubble are form between the protecting layer 11 and the connecting surfaces 1000. The protecting layer 11 abuts against the connecting surfaces 1000 of the nitride-based dies 100, and the protecting layer 11 and the connecting bumps 12 cover all the connecting surfaces 1000 and the connecting pads 1001. Therefore, the connecting bumps 12 near the connecting surfaces 1000 are hold by the protecting layer 11, and electromigration of the connecting bumps 12 can be prevented.

In one aspect, the protecting layer 11 in this embodiment is formed among the connecting bumps 12. To be specific, the protecting layer 11 fills up the space among the connecting bumps 12. The protecting layer 11 is solid, and the connecting bumps 12 can be hold firmly on a surface of the nitride-based semiconductor wafer 10, and the connecting bumps 12 can maintain electrically connected to the connecting pads 1001.

In one aspect, each of the connecting bumps 12 in this embodiment has a width W1 in a direction d1, and a width W2 in a direction d2. The direction d1 and the direction d2 are perpendicular, and the direction d2 and a normal N of the polished plane 120 of the connecting bump 12 are parallel. The width W1 is larger than the width W2. Therefore, the connecting bump 12 can provide an electrical connection with low resistance because the width W1 is wide enough to reduce the resistance. Also, the width W2 is short, and the electrical resistance of the connecting bump 12 is further reduced.

In this embodiment, every polished plane 120 of the connecting bump 12 has a width W3 in the direction d1, and the width W1 is larger than the width W3. To be specific, the connecting bump 12 inside the protecting layer 11 is wider than the polished plane 120 of the connecting bump 12. Therefore, the protecting layer 11 can hold the connecting bump 12 firmly. Also, no bubble or air gap is formed around the connecting bumps 12, and, therefore; the electromigration can be prevented.

In one aspect, the protecting layer 11 in this embodiment has a polished plane 110. The polished plane 110 faces backward towards the connecting surfaces 1000 of the nitride-based dies 100. The polished planes 120 and the polished plane 110 are coplanar. The polished planes 120 and the polished plane 110 can be formed in a single polishing step, and the polished plane 110 is located among the polished planes 120. Therefore, the polished plane 110 can hold the polished planes 120 closely and firmly, and the polished planes 120 can provide proper electrical connection areas.

Also, the polished planes 120 and the polished plane 110 can be formed through single polishing process. Since the polished plans 120 and the polished plane 110 can be formed in the same step, and the connecting bumps 12 are embedded in the protecting layer 11, we can easily form a plane surface on the nitride-based semiconductor device 1A that has proper electrically connecting ability.

Moreover, the polished planes 120 and the polished plane 110 form a solidified and continuous surface together. Therefore, the connecting bumps 12 and the protecting layer 11 of the nitride-based semiconductor device 1A can endure falling tests, high temperature tests, and low temperature tests. In other words, the connecting bumps 12 and the protecting layer 11 is firm, solid, and durable.

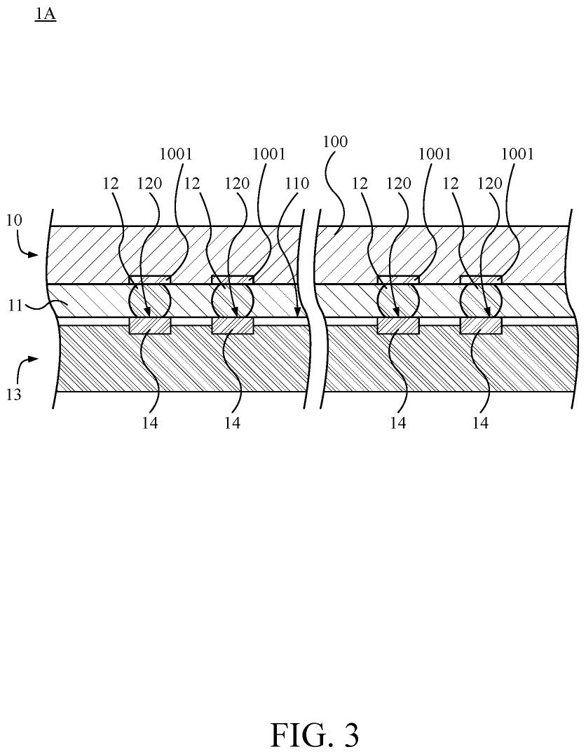

FIG. 3 is another side sectional view of the nitride-based semiconductor device according to the embodiments of the present disclosure. Referring to FIG. 3, the nitride-based semiconductor device 1A of this embodiment comprises a plurality of printed circuit boards 13.

Each of the printed circuit boards 13 electrically connects the polished planes 120 of the connecting bumps 12 that are connected to one of the nitride-based dies 100. To be specific, every nitride-based die 100 is electrically connected to one of the printed circuit boards 13 through the polished planes 120 of the connecting bumps 12 that are connected to the connecting pads of the nitride-based die 100, and the connecting bumps 12 embedded in the protecting layer 11 can maintain a good electrical connection with the printed circuit board 13. In other words, the protecting layer 11 holds the connecting bumps 12 closely and firmly, and the connecting bumps 12 can form a firm and steady electrical connection between the nitride-based semiconductor wafer 10 and the printed circuit boards 13.

Moreover, in every nitride-based die 100 of the nitride-based semiconductor wafer 10, the protecting layer 11 is not connected to the printed circuit boards 13. To be specific, the nitride-based semiconductor device 1A comprises a plurality of connecting pads 14, and the connecting pads 14 are embedded in the printed circuit boards 13. Every nitride-based die 100 is electrically connected to the printed circuit board 13 through the connecting pads 1001, the connecting bumps 12, and the connecting pads 14, and the connecting pads 14 covers the polished planes 120 of the connecting bumps 12. Only the connecting pads 14 touch the polished planes 120 of the connecting bumps 12, and the printed circuit board 13 doesn't touch the connecting bumps 12 or the protecting layer 11. Therefore, electromigration can be prevented.

Moreover, the protecting layer 11 holds the connecting bumps 12, and a gap is remained between every printed circuit board 13 and the protecting layer 11. Therefore, a good electrical connection is form with the connecting bumps 12, and the gap between the printed circuit board 13 and the protecting layer 11 provide a good heat dissipation ability.

The connecting pads 1001 and the connecting pads 14 may include metals or metal compound. The exemplary materials of the metals or metal compounds can include, for example but are not limited to, W, Au, Pd, Ti, Ta, Co, Ni, Pt, Mo, TiN, TaN, metal alloys thereof, or other metallic compounds.

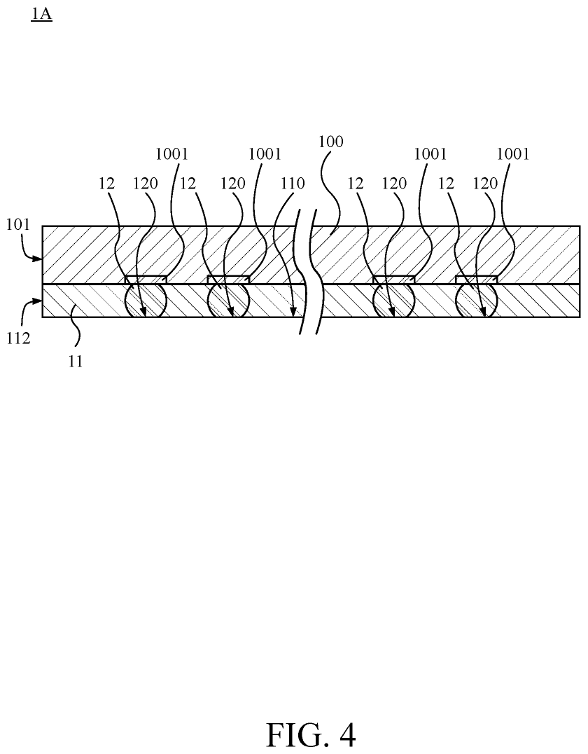

FIG. 4 is a side sectional view according to a cutting plane line 4 in FIG. 1. Referring to FIG. 4, in this embodiment, the protecting layer 11 comprises a side surface 112, and a projection of the side surface 112 on the nitride-based semiconductor wafer 10 is coincide with a boarder 101 of the nitride-based semiconductor wafer 10. The protecting layer 11 is conformally formed on the nitride-based semiconductor wafer 10, and the solidified protecting layer 11 and the embedded connecting bumps 12 can endure the polishing process, and the yield of the nitride-based semiconductor device 1A is improved.

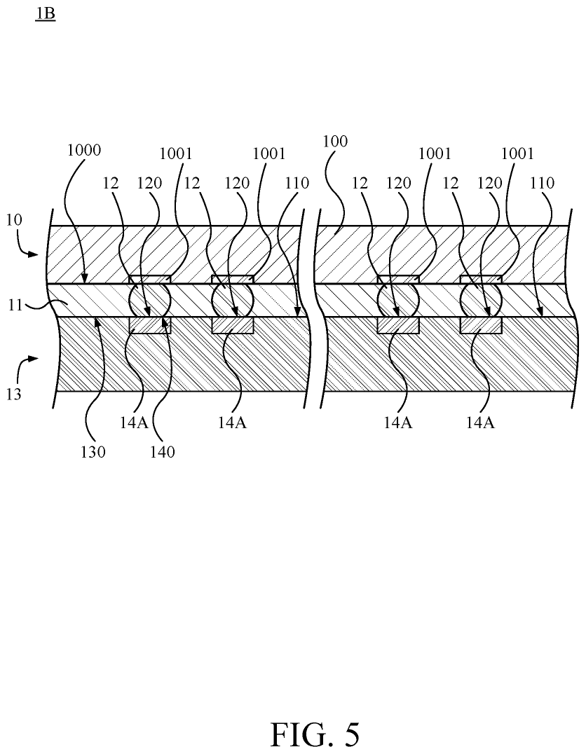

FIG. 5 is a side sectional view of a nitride-based semiconductor device according to some embodiments of the present disclosure. Referring to FIG. 5, in this embodiment, the nitride-based semiconductor device 1B comprises a nitride-based semiconductor wafer 10, a protecting layer 11, a plurality of connecting bumps 12, and a plurality of printed circuit board 13. The nitride-based semiconductor wafer 10, and the protecting layer 11 are similar to the nitride-based semiconductor wafer 10 and the protecting layer 11 of the nitride-based semiconductor device 1A.

The nitride-based semiconductor wafer 10 has nitride-based dies 100. Each of the nitride-based dies 100 has a connecting surface 1000 and a plurality of connecting pads 1001. The connecting pads 1001 are embedded in the connecting surface 1000. The protecting layer 11 is disposed on the connecting surface 1000, and the connecting bumps 12 are embedded in the protecting layer 11. Every connecting bump 12 has a polished plane 120, and the protecting layer 11 has a polished plane 110. The polished planes 120 and the polished plane 110 are coplanar.

In this embodiment, the nitride-based semiconductor device 1B comprises a plurality of connecting pads 14A, and the connecting pads 14A are embedded in the printed circuit board 13. A top surface 130 of the printed circuit board 13 and connecting surfaces 140 of the connecting pads 14 are coplanar. The connecting surfaces 140 cover the polished planes 120 and part of the polished plane 110 near the polished planes 120, and the top surface 130 of the printed circuit board 13 covers the rest of the polished plane 110 of the protecting layer 11.

The connecting pads 1001, the connecting bumps 12, and the connecting pads 14A are enclosed by the nitride-based die 100, the protecting layer 11, and the printed circuit board 13. Therefore, electromigration is further avoided. The connecting bumps 12 can provide a durable electrical connection.

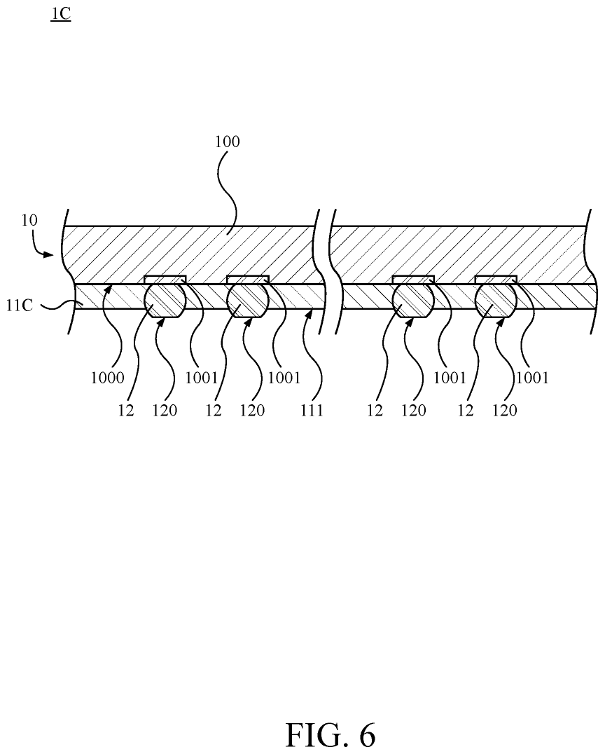

FIG. 6 is a side sectional view of a nitride-based semiconductor device according to some embodiments of the present disclosure. Referring to FIG. 6, the nitride-based semiconductor device 1C comprises a nitride-based semiconductor wafer 10, a protecting layer 11C and a plurality of connecting bumps 12. The nitride-based semiconductor wafer 10 comprises a plurality of nitride-based dies 100. Each of the nitride-based dies 100 comprises a connecting surface 1000 and a plurality of connecting pads 1001. The connecting pads 1001 are embedded in the connecting surface 1000. The protecting layer 11C is disposed on the connecting surface 1000 of the nitride-based die 100, and the connecting bumps 12 are embedded in the protecting layer 11C. Every connecting bump 12 connects one of the connecting pads 1001, and every connecting bump 12 has a polished plane 120, and the polished plane 120 is free from the protecting layer 11C. In other words, the protecting layer 11C exposes part of every connecting bump 12.

Moreover, in this embodiment, part of every connecting bump 12 protrudes from the protecting layer 11C. The polished plane 120 is formed on the bottom of the connecting bump 12, and the part of connecting bump 12 that is adjacent to the polished plane 120 is also exposed by the protecting layer 11C. The polished planes 120 of the connecting bumps 12 are coplanar, and the protecting layer 11C can hold most of the part of every connecting bump 12, and the rest of every connecting bump 12 is free from protecting layer 11C. Therefore, the connecting bumps 12 can form an electrical connection properly, and the connection may have good heat dissipation. Also, the protecting layer 11C can absorb stress and prevent electromigration of the connecting bumps 12 near the connecting surface 1000.

In one aspect, the protecting layer 11C has a bottom surface 111, and the bottom surface 111 and the connecting surfaces 1000 are parallel. A constant distance is remained between the bottom surface 111 and the connecting surfaces 1000, and the thickness of the protecting layer 11C remains the same. Therefore, the protecting layer 11C can provide the same protection and hold the connecting bumps 12 equally. In other words, the connecting bumps 12 and the protecting layer 11C can provide a durable electrical connection.

In one aspect, measuring from the connecting surfaces 1000 of the nitride-based dies 100, the polished planes 120 of the connecting bumps 12 are located higher than the bottom surface 111. The polished planes 120 of the connecting bumps 12 and the bottom surface 111 of the protecting layer 11C are located in different level of height, and the bottom surface 111 is not formed by the polishing process that forms the polished planes 120 of the connecting bumps 12. Therefore, an electrical connection can be easily form with the polished planes 120 of the connecting bumps 12.

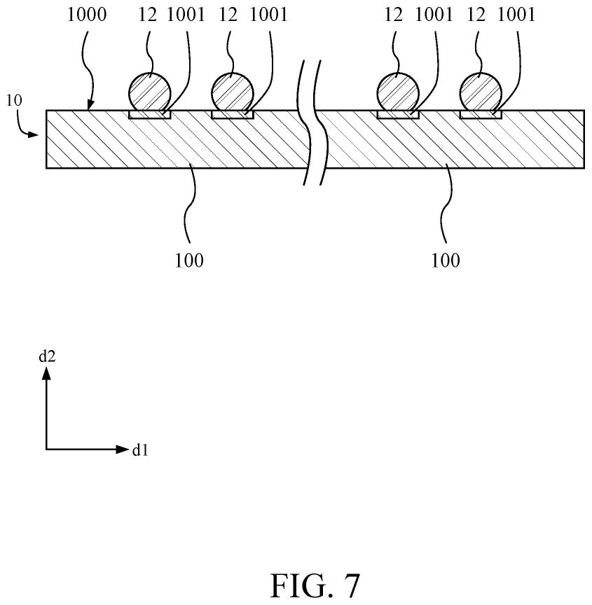

FIGS. 7-12 are side sectional views of steps of a manufacturing method of nitride-based semiconductor device of some embodiments of the present disclosure. Referring to FIG. 7, in this embodiment, the manufacturing method comprises: disposing a plurality of connecting bumps 12 on a nitride-based semiconductor wafer 10. The nitride-based semiconductor wafer 10 comprises a plurality of nitride-based dies 100. The nitride-based die 100 comprises a connecting surface 1000 and a plurality of connecting pads 1001. The connecting pads 1001 are embedded in the connecting surface 1000.

In this embodiment, every connecting bump 12 is disposed directly on one of the connecting pads 1001, and every connecting pads 1001 is carrying one of the connecting bumps 12. In other words, every connecting bump 12 connects one of the connecting pads 1001. Every connecting bump 12 form an interface with one of the connecting pads 1001. In direction d1, the interface has a width that is shorter than a width of the connecting bump 12. To be specific, the connecting bump 12 covers a middle area of the connecting pad 1001, and the periphery of the connecting pad 1001 is exposed by the connecting bump 12. In other words, periphery of every connecting pad 1001 is free from the connecting bump 12.

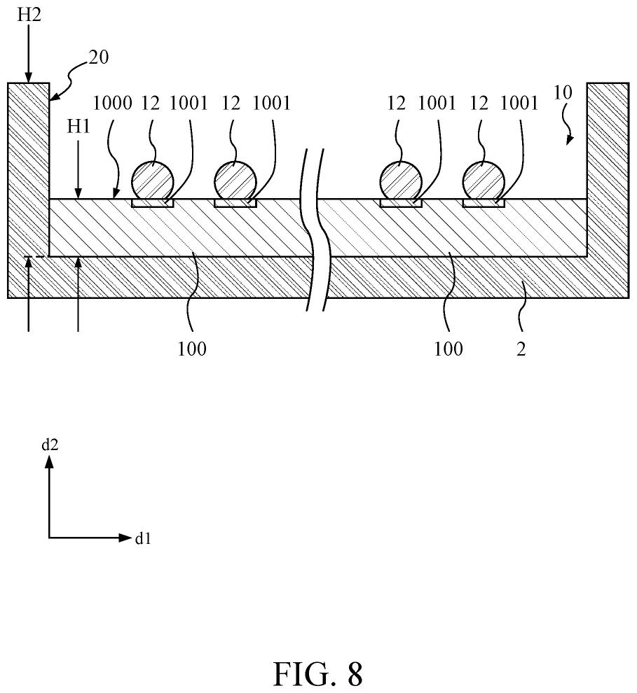

Referring to FIG. 8, in this embodiment, after the step of disposing the connecting bumps 12, the manufacturing method comprises: disposing the nitride-based semiconductor wafer 10 in a container 2. After the nitride-based semiconductor wafer 10 is disposed in the container 2, the connecting bumps 12 are facing upward. In other words, the connecting surface 1000 is not touching the container 2.

In this embodiment, the thickness H1 of the nitride-based wafer 10 is 1 mm, and the height H2 of the inner wall 20 of the container 2 is 3 mm. Therefore, the inner wall 20 is higher than the nitride-based wafer 10, and the inner wall 20 is higher than the top surfaces of the connecting bumps 12 on the nitride-based wafer 10. In some embodiments, the thickness H1 of the nitride-based wafer 10 falls in a range from 0.5 mm to 2 mm, and the height H2 of the inner wall 20 of the container 2 falls in a range from 2.5 mm to 4 mm. The height H2 is much higher than the thickness H1, and therefore the inner wall 20 is higher than the top surface of the connecting bumps 12 on the nitride-based wafer 10.

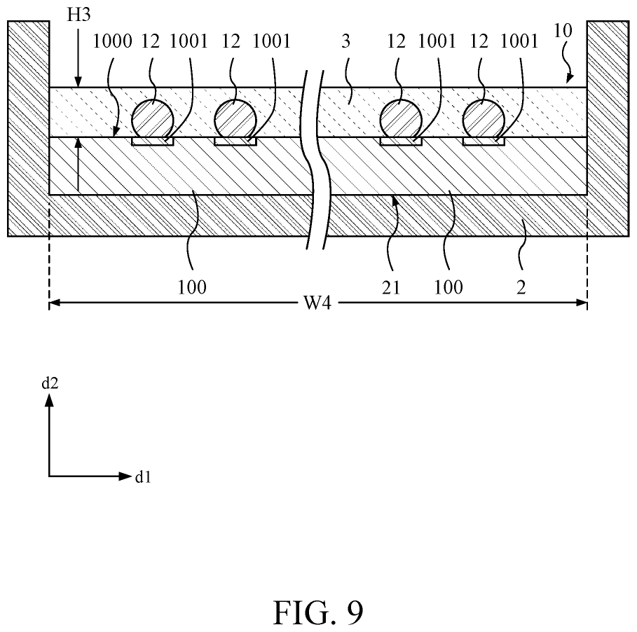

Referring to FIG. 9, in this embodiment, after the step of disposing the nitride-based semiconductor wafer 10 in the container 2, the manufacturing method comprises: disposing a dielectric material 3 on the nitride-based semiconductor wafer 10 in the container 2. For example, the dielectric material 3 may include epoxy resin.

In this embodiment, the dielectric material 3 is fluid, and the dielectric material 3 fills up the space among the connecting bumps 12. Most of the connecting surface 1000 is loaded with the dielectric material 3, and the peripheries of the connecting pads 1001 are covered with dielectric material 3 as well.

The height H3 of the dielectric material 3 may be 300 μm, and the dielectric material 3 covers the tops of the connecting bumps 12. In some embodiments, the height H3 of the dielectric material 3 falls in a range from 100 μm to 1 mm. In some other embodiments, the height H3 of the dielectric material 3 can be much higher than the height of the connecting bumps 12, and, therefore; the dielectric material 3 can encapsulate and protect the connecting bumps 12.

In one aspect, the container 2 has an inner bottom surface 21, and the inner bottom surface 21 carries the nitride-based semiconductor wafer 10. A width or diameter of the inner bottom surface 21 of the container 2 and a width or diameter of the nitride-based semiconductor wafer 10 are similar. To be specific, the width W4 or diameter of the bottom surface 21 is slightly longer than the width or diameter of the nitride-based semiconductor wafer 10. In other words, an area of the inner bottom surface 21 and an area of the nitride-based semiconductor wafer 10 are similar. Therefore, most of the dielectric material 3 is remain on the connecting surface 1000. In some embodiment, the area of the inner bottom surface 21 and the area of the nitride-based semiconductor wafer 10 are the same, and the dielectric material 3 only touches the connecting surface 1000, the connecting pads 1001, and the connecting bumps 12.

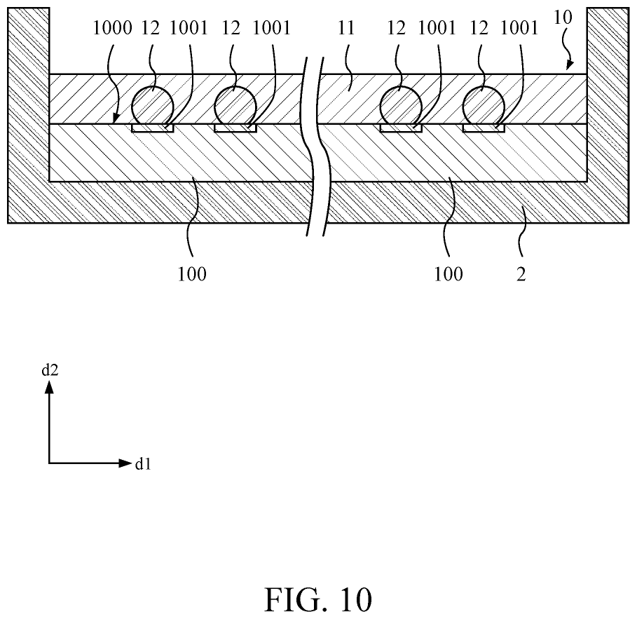

Referring to FIG. 10, in this embodiment, after the step of disposing the dielectric material 3, the manufacturing method comprises: solidifying the dielectric material 3 and form a protecting layer 11. The solidifying process in this embodiment comprises: heating the dielectric material 3. For example, the dielectric material 3 on the nitride-based semiconductor wafer 10 is heated to 130° C., and the protecting layer 11 is formed. In other words, the dielectric material 3 is solidified through heating. However, in some embodiments, the dielectric material 3 can be solidify through other process, depending on the material of the dielectric material 3.

In this embodiment, the protecting layer 11 is disposed on the connecting surface 1000 of the nitride-based dies 100. The protecting layer 11 encapsulates the connecting bumps 12 on the nitride-based die 100, and no bubble or air gap is formed between the connecting bumps 12, and no bubble or air gap is formed on the connecting pads 1001 either. The connecting bumps 12 on the connecting pads 1001 are totally covered by the protecting layer 11.

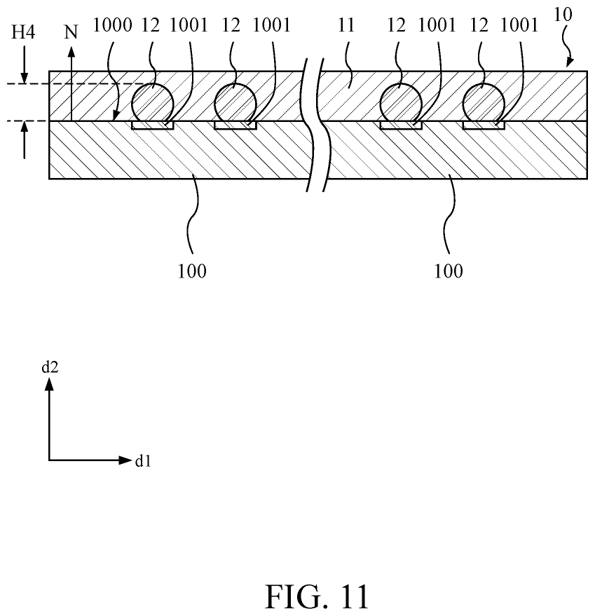

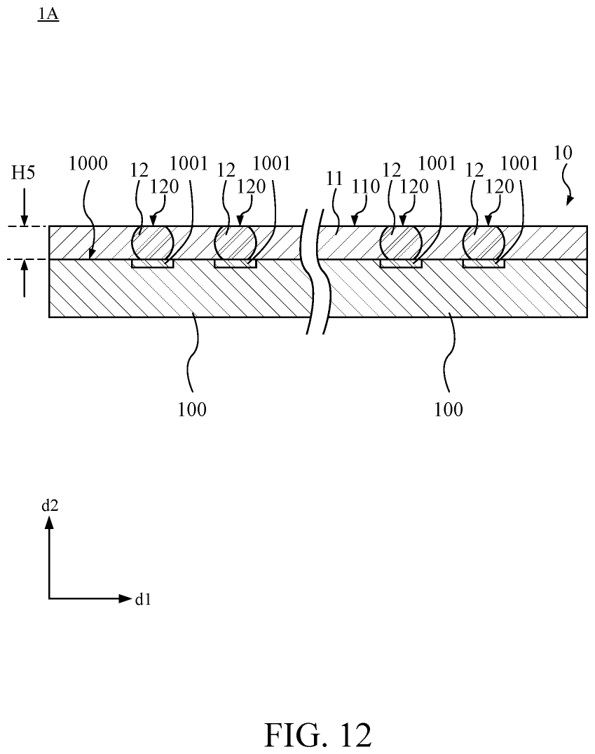

Referring to FIGS. 11 and 12, in this embodiment, after the step of solidifying the dielectric material 3, the manufacturing method comprises: polishing the connecting bumps 12. In this step, a polished plane 120 is formed on every connecting bump 12, and a nitride-based semiconductor device 1A is formed.

In this embodiment, the polished planes 120 of the connecting bumps 12 can form electrical connection with other devices, such as printed circuit board. No bubble and gap are formed between the connecting bumps 12 and the protecting layer 11, and, therefore; electromigration can be avoided. Also, the protecting layer 11 can absorb the stress applied on the connecting bumps 12, and, therefore; the nitride-based semiconductor device 1A can provide a good electrical connection through the connecting bumps 12.

To be specific, referring to FIG. 11, in this embodiment, the step of polishing the connecting bumps 12 comprises: removing the nitride-based semiconductor wafer 10, the protecting layer 11, and the connecting bumps 12 from the container 2. The protecting layer 11 encapsulates the connecting bumps 12 on the connecting surfaces 1000 of the nitride-based dies 100, and, therefore; the nitride-based semiconductor wafer 10, the protecting layer 11, and the connecting bumps 12 can be removed from the container 2 easily.

Referring to FIG. 12, in this embodiment, the protecting layer 11 and the connecting bumps 12 are both being polished. In other words, the step of polishing the connecting bumps 12 comprises: polishing the protecting layer 11. In this step, a polished plane 110 is formed on the protecting layer 11, and the polished plane 110 and the polished planes 120 are coplanar.

In a horizontal plane, the polished planes 120 of the connecting bumps 12 are surrounded by the polished plane 110 of the protecting layer 11, and the polished planes 120 can be protected by the polished plane 110, and electromigration can be avoided.

Moreover, the connecting bumps 12 have a 25 percent height reduction following polishing. Referring to FIG. 11, before polishing, the connecting bump 12 has a height H4 in direction d2, which is parallel to the normal N of the connecting surface 1000. Referring to FIG. 12, after being polished, the connecting bump 12 has a height H5 in direction d2. The heights match the equation:

$${H}_{5} = \frac{3}{4} {H}_{4}$$

Therefore, the polished plane 120 provide enough area for electrical connection. Also, with the protection of the protecting layer 11, shapes of the connecting bumps 12 will remain the same after being connected to other devices, and no bubble or air gap will be formed, and electromigration can be avoided.

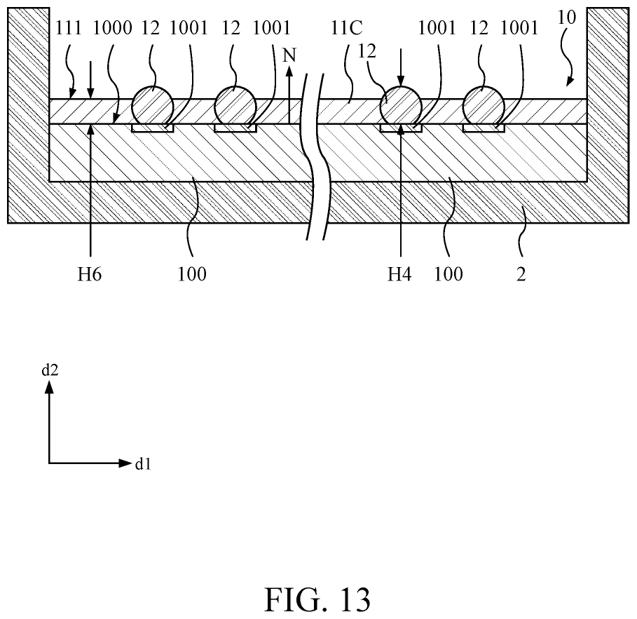

FIG. 13-15 are side sectional view of steps of a manufacturing method of nitride-based semiconductor device of some embodiments of the present disclosure. Referring to FIG. 13, in this embodiment, the manufacturing method is similar to the manufacturing method referring to FIGS. 7-12. However, in this embodiment, after the nitride-based semiconductor wafer 10 is disposed in the container 2, the dielectric material is disposed and solidified, and the protecting layer 11C is formed. The protecting layer 11C has a height H6 in the direction d2, which is parallel to the normal N of the connecting surface 1000. The connecting bump 12 has a height H4. The height H6 of the protecting layer 11C is shorter than the height H4 of the connecting bump 12.

For example, the heights match the equation:

$${H}_{6} = \frac{2}{3} {H}_{4}$$

Therefore, the connecting bumps 12 protrude from the bottom surface 111 of the protecting layer 11C.

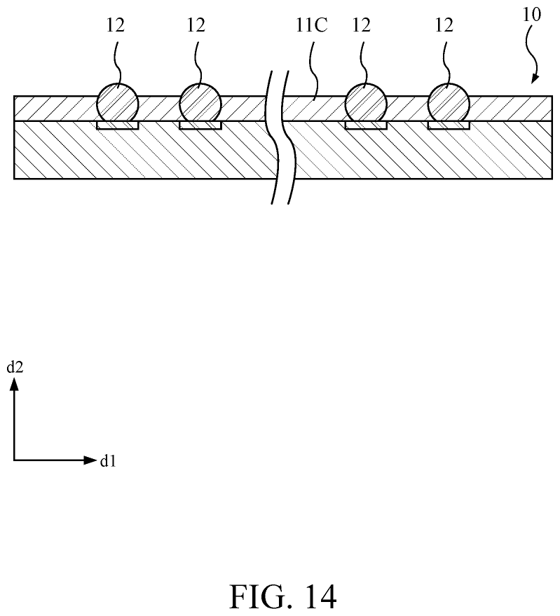

Referring to FIG. 14, after the protecting layer 11C is formed, the nitride-based semiconductor wafer 10, the protecting layer 11C, and the connecting bumps 12 are removed from the container 2.

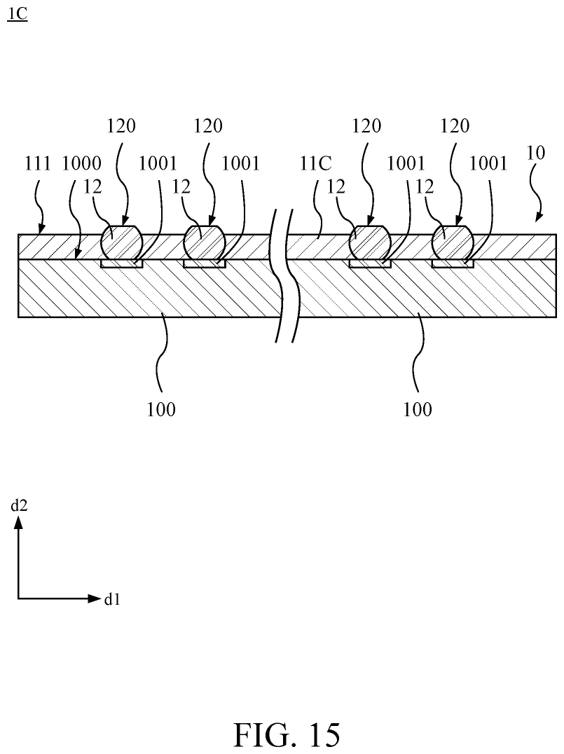

Referring to FIG. 15, after the nitride-based semiconductor wafer 10 is removed, the connecting bumps 12 are polished, and a polished plane 120 is formed on every connecting bump 12, and the nitride-based semiconductor device 1C is formed.

In this embodiment, the polished planes 120 protrude from the bottom surface 111 of the protecting layer 11C, and most of every connecting bump 12 is embedded in the protecting layer 11C. Therefore, the protecting layer 11C can protect and absorb stress, and the polished planes 120 of the connecting bumps 12 can form electrical connection easily. Also, no bubble or air gap is formed between the connecting bumps 12 and the protecting layer 11C, and electromigration may be avoided.

The embodiments were chosen and described in order to best explain the principles of the invention and its practical application, thereby enabling others skilled in the art to understand the invention for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to +0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents

unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the FIGS. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A nitride-based semiconductor device comprising:
a nitride-based semiconductor wafer comprising a plurality of nitride-based dies, and each of the nitride-based dies comprised:
a connecting surface; and
a plurality of connecting pads embedded in the connecting surface;
a protecting layer disposed on the connecting surfaces of the nitride-based dies; and
a plurality of connecting bumps embedded in the protecting layer, wherein every connecting bump connects one of the connecting pads, and every connecting bump has a first polished plane, and the first polished plane is free from the protecting layer.

2. The nitride-based semiconductor device of claim 1, wherein the protecting layer has a second polished plane, and the second polished plane faces backward towards the connecting surfaces of the nitride-based dies, and the first polished planes and the second polished plane are coplanar.

3. The nitride-based semiconductor device of claim 2, wherein the first polished planes and the second polished plane form a solidified and continuous surface together.

4. The nitride-based semiconductor device of claim 1, wherein part of every connecting bump protrudes from the protecting layer.

5. The nitride-based semiconductor device of claim 4, wherein the protecting layer has a bottom surface, and the bottom surface and the connecting surfaces are parallel.

6. The nitride-based semiconductor device of claim 5, wherein, measuring from the connecting surfaces of the nitride-based dies, the first polished planes are located higher than the bottom surface.

7. The nitride-based semiconductor device of claim 1 further comprising a plurality of printed circuit boards, wherein each of the printed circuit boards electrically connects the first polish planes of the connecting bumps connected to one of the nitride-based die.

8. The nitride-based semiconductor device of claim 7, wherein the protecting layer is not connected to the printed circuit boards.

9. The nitride-based semiconductor device of claim 7, wherein a gap is formed between every printed circuit board and the protecting layer.

10. The nitride-based semiconductor device of claim 1, wherein no gap or bubble are form between the protecting layer and the connecting surfaces.

11. The nitride-based semiconductor device of claim 1, wherein, in a first direction, each of the connecting bumps has a first width, and, in a second direction, the connecting bump has a second width, and the first width is larger than the second width, and the first direction and the second direction are perpendicular, and the second direction and a normal of the first polished plane of the connecting bump are parallel.

12. The nitride-based semiconductor device of claim 1, wherein the protecting layer is formed among the connecting bumps.

13. The nitride-based semiconductor device of claim 1, wherein the protecting layer comprises a side surface, and a projection of the side surface on the nitride-based semiconductor wafer is coincide with a boarder of the nitride-based semiconductor wafer.

14. The nitride-based semiconductor device of claim 1, wherein the nitride-based semiconductor wafer has a plurality of die areas and a dicing area, and the dicing area is located among the die areas, and each of the nitride-based dies is disposed in one of the die areas, and the protecting layer covers a surface of the nitride-based semiconductor wafer in the dicing area.

15. The nitride-based semiconductor device of claim 1, wherein the first polished planes are coplanar.

16. A manufacturing method of nitride-based semiconductor device, comprising:
disposing a plurality of connecting bumps on a nitride-based semiconductor wafer;
disposing the nitride-based semiconductor wafer in a container, wherein the connecting bumps are facing upward;
disposing a dielectric material on the nitride-based semiconductor wafer in the container;
solidifying the dielectric material and form a protecting layer; and
polishing the connecting bumps, wherein a first polished plane is formed on every connecting bump,
wherein the nitride-based semiconductor wafer comprises a plurality of nitride-based dies, and the nitride-based die comprises a connecting surface and a plurality of connecting pads embedded in the connecting surface, and every connecting bump connects one of the connecting pads, and the protecting layer is disposed on the connecting surfaces of the nitride-based dies.

17. The manufacturing method of claim 16, wherein the step of polishing the connecting bump comprises:
polishing the protecting layer,
wherein a second polished plane is formed on the protecting layer, and the first polished planes and the second polished plane are coplanar.

18. The manufacturing method of claim 16, wherein the container has an inner bottom surface, and the inner bottom surface carries the nitride-based semiconductor wafer, and an area of the inner bottom surface and an area of the nitride-based semiconductor wafer are similar or the same.

19. The manufacturing method of claim 16, wherein the dielectric material is solidified through heating.

20. The manufacturing method of claim 16, wherein the connecting bumps have a 25 percent height reduction following polishing.

21-25. (canceled)
